(19) United States
(12) Patent Application Publication
(10) Pub. No.: US 2026/0313853 A1
(43) Pub. Date: Oct. 8, 2026

(54) CONTAINERIZED DATA CENTER COOLING SYSTEM

(71) Applicant: AirSys Holding, Inc., Greer, SC (US)

(72) Inventors: Mengyuan Yuan, Anderson, SC (US); Nan Chen, Alpharetta, GA (US); Yunshui Chen, Greer, SC (US); Zhipeng Zhao, Anderson, SC (US)

(21) Appl. No.: 19/555,012

(22) Filed: Mar. 3, 2026

Related U.S. Application Data
(60) Provisional application No. 63/782,795, filed on Apr. 3, 2025.

(51) Int. Cl. H05K 7/20; H05K 7/14

(52) U.S. Cl. CPC H05K 7/20772; H05K 7/1497; H05K 7/20263; H05K 7/20272

(57) ABSTRACT

A containerized data center cooling system may include a shipping container defining an interior volume, a plurality of server cassettes removably supported within the interior volume, and a self-contained primary liquid cooling loop disposed entirely within each server cassette. The primary liquid cooling loop may include a primary coolant reservoir, a pump configured to circulate a primary liquid coolant, one or more coolant delivery elements configured to deliver the primary liquid coolant directly onto one or more heat-generating electronic components, and a heat exchanger affixed to the server cassette and thermally coupled to the primary liquid cooling loop. Each server cassette includes the one or more heat-generating electronic components.

### PRIORITY

This patent application claims priority from Provisional United States Patent Application number 63/782,795, filed Apr. 3, 2025, entitled DISTRIBUTED SERVER RACK COOLING SYSTEM and naming Nan Chen, Mengyuan Yuan, Zhipeng Zhao, and Yunshui Chen as the inventors, the disclosure of which is incorporated herein in its entirety, by reference.

### FIELD

Illustrative embodiments of the invention generally relate to data center server cooling and servicing and, more particularly, various embodiments of the invention relate to a cooling and servicing system for server cassettes in racks within storage containers.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Data center cooling maintains the right temperatures for servers and associated equipment to prevent overheating and server shutdown and ensure reliable and efficient performance. Formerly, data centers used various forms of air cooling and refrigeration to maintain proper equipment temperatures. However, with dramatic increases in processor and computer operating speeds, traditional air cooling is insufficient. Newer systems use various forms of liquid or oil cooling to maintain equipment temperatures.

### SUMMARY OF VARIOUS EMBODIMENTS

In accordance with one embodiment of the invention, containerized data center cooling system may include a shipping container defining an interior volume, a plurality of server cassettes removably supported within the interior volume, and a self-contained primary liquid cooling loop disposed entirely within each server cassette. The primary liquid cooling loop may include a primary coolant reservoir, a pump configured to circulate a primary liquid coolant, one or more coolant delivery elements configured to deliver the primary liquid coolant directly onto one or more heat-generating electronic components, and a heat exchanger affixed to the server cassette and thermally coupled to the primary liquid cooling loop. Each server cassette includes the one or more heat-generating electronic components.

In accordance with other embodiments, the containerized data center cooling system may include a secondary liquid cooling loop fixed relative to the shipping container and thermally coupled to the heat exchanger of each server cassette. The secondary liquid cooling loop may include coolant piping, one or more single-phase pumps, configured to circulate a secondary liquid coolant through the coolant piping, and one or more heat rejection devices, coupled through the coolant piping to the one or more single-phase pumps, configured to remove heat from the secondary liquid coolant.

In accordance with other embodiments, the one or more heat rejection devices include dry coolers mounted on one or more exterior surfaces of the shipping container.

In accordance with other embodiments, the primary liquid cooling loop of each server cassette is fluidly isolated from the primary liquid cooling loops of other server cassettes and from the secondary liquid cooling loop.

In accordance with other embodiments, the primary liquid cooling loop of each server cassette is thermally coupled to the secondary liquid cooling loop through the heat exchanger.

In accordance with other embodiments, removal of a server cassette from the shipping container does not interrupt circulation of the secondary liquid cooling loop to remaining server cassettes.

In accordance with other embodiments, the containerized data center cooling system may also include an internal maintenance station positioned within the shipping container and configured to permit removal, servicing, and reinstallation of individual server cassettes entirely within the container.

In accordance with other embodiments, the containerized data center cooling system may also include an internal trolley movable within the shipping container and configured to transport server cassettes between server racks removably supporting the plurality of server cassettes and the maintenance station.

In accordance with other embodiments, the trolley may include a vertically adjustable elevator configured to align a server cassette with different shelf heights.

In accordance with other embodiments, a transportable data center cooling apparatus may include a shipping container, a plurality of removable server cassettes disposed within the shipping container, and a secondary liquid cooling loop thermally coupled to each server cassette by a respective cassette-mounted heat exchanger. Each server cassette my include an internal, closed primary liquid cooling loop configured to cool one or more electronic components within the server cassette.

In accordance with other embodiments, the primary liquid cooling loop of each server cassette is operable independently of the primary liquid cooling loops of other server cassettes.

In accordance with other embodiments, the secondary liquid cooling loop is configured to continue cooling remaining server cassettes while one server cassette is decoupled from the secondary liquid cooling loop.

In accordance with other embodiments, the transportable data center cooling apparatus may also include an internal maintenance station positioned within the shipping container and configured to permit removal, servicing, and reinstallation of individual server cassettes entirely within the container.

In accordance with other embodiments, the transportable data center cooling apparatus may also include an internal trolley movable within the shipping container and configured to transport server cassettes between the maintenance station and server racks within the container removably supporting the plurality of server cassettes.

In accordance with other embodiments, the trolley includes a vertically adjustable elevator configured to align a server cassette with different shelf heights.

In accordance with other embodiments, a method of cooling and servicing a containerized data center may include circulating a secondary liquid coolant through a secondary cooling loop fixed relative to a shipping container, circulating a primary liquid coolant within a first server cassette using a primary cooling loop disposed entirely within the first server cassette, thermally coupling the primary cooling loop to the secondary cooling loop through a heat exchanger mounted to the first server cassette, removing the first server cassette from a rack location within the shipping container, and servicing the first server cassette at a maintenance station within the shipping container.

In accordance with other embodiments, removing the server cassette may include moving the server cassette using a wheeled trolley within the container to the maintenance station.

In accordance with other embodiments, servicing the server cassette includes draining and refilling a primary liquid coolant associated with the server cassette.

In accordance with other embodiments, servicing the first server cassette may include draining and refilling a primary liquid coolant associated with the server cassette.

In accordance with other embodiments, circulating the primary liquid coolant within the first server cassette may include spraying the primary liquid coolant onto one or more heat sinks within the first server cassette.

In accordance with other embodiments, the primary liquid cooling loop of the first server cassette may be operable independently of the primary liquid cooling loops of other server cassettes.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a first front external isometric view of a shipping container based data center cooling system in accordance with illustrative embodiments of the invention.

FIG. 2 schematically shows a second front external isometric view of a shipping container based data center cooling system in accordance with illustrative embodiments of the invention.

FIG. 3 schematically shows a first front internal isometric view of a data center cooling system with side container surfaces removed in accordance with illustrative embodiments of the invention.

FIG. 4 schematically shows a first rear internal isometric view of a data center cooling system with side container surfaces removed in accordance with illustrative embodiments of the invention.

FIG. 5 schematically shows a second rear internal isometric view of a data center cooling system with side container surfaces removed in accordance with illustrative embodiments of the invention.

FIG. 6 schematically shows a second front internal isometric view of a data center cooling system with side container surfaces removed in accordance with illustrative embodiments of the invention.

FIG. 7 schematically shows a maintenance station of a container-based data center cooling system in accordance with illustrative embodiments of the invention.

FIG. 8 schematically shows a block diagram of primary and secondary cooling loops of a container-based data center cooling system in accordance with illustrative embodiments of the invention.

### DESCRIPTION OF ILLUSTRATIVE EMBODIMENTS

In containerized data centers, conventional liquid cooling architectures are poorly suited for in-place servicing, as removal of a server module often requires draining shared coolant loops or interrupting cooling to adjacent equipment. Data centers contain large numbers of computers operating in parallel and continuously. The computers are generally servers, each including one or more central processing units (CPUs) and graphical processing units (GPUs). In one embodiment, each server may be in a cassette standard from factor and stored in one or more racks with other similar or dissimilar cassettes. Typically, the racks containing servers/cassettes may be located in a data center of a building. In addition to the racks, the data center may include supporting equipment to distribute power and provide cooling to the servers.

In illustrative embodiments, the data center may be potentially portable rather than permanently installed in a dedicated room or rooms of a building. One way to allow a data center to be portable and easily relocated is to install the principal components (racks, servers, power distribution, and cooling) within a standard shipping container.

Shipping containers are available in several different lengths to accommodate different volumes of shipped material. For example, shipping containers may be available in 8 foot widths and 10 foot, 20 foot (most common), 40 foot, 45 foot, and larger lengths. Standard shipping container dimensions facilitate efficient vertical stacking on ships and in warehouses. By mounting key data center components within a standard shipping container, a data center may be physically located or relocated to any practical location without an expensive building outfitting process.

Data centers generally includes many server computers (i.e., computing equipment) organized into groups of racks. Each rack may include any number of servers but typically include 10-30 identical server computers in a cassette or blade format that may be individually added to or removed from a rack. Each rack often includes an associated cooling system to cool very high temperature electronic components, such as central processing units (CPUs) and/or graphical processing units (GPUs). In some cases, other components such as memory modules/devices, northbridge, or southbridge components may be individually cooled as well. Each high-temperature component may have an associated heat sink that is cooled by air, a liquid, or a combination of air and a liquid. Older servers and components produced much less heat than modern components, so air cooling was often sufficient. However, present day individual components may produce over 500 watts of heat, requiring more advanced liquid cooling systems.

Each server cassette typically includes a server motherboard and various components supporting a primary cooling loop. The primary cooling loop transfers heat from the high temperature server components to a secondary cooling loop and returns a recirculated cooled liquid coolant to continue cooling the server components. Illustrative embodiments address this problem with an advanced liquid cooling system for container-based data center applications. Details of various embodiments are discussed below.

The disclosed cooling architecture provides technical advantages including reduced service downtime, reduced risk of coolant leakage during maintenance, and improved thermal isolation between server cassette modules.

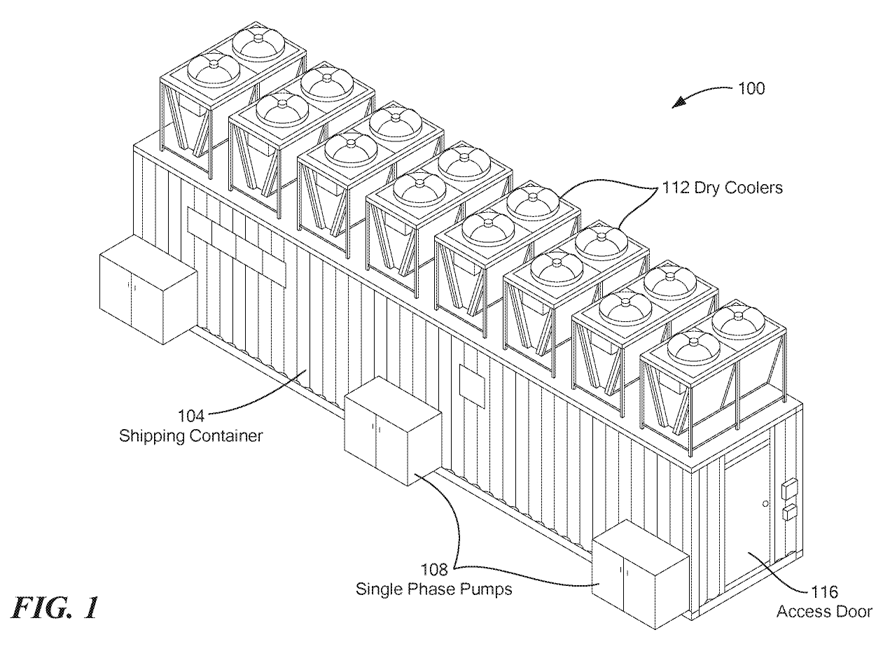

Referring to FIG. 1, a first front external isometric view of a shipping container based data center cooling system 100 in accordance with illustrative embodiments of the invention is shown. The first isometric view is from a front left perspective. In one embodiment, the container 104 may be based on a standard 40’ international shipping container. The container 104 includes one or more access doors 116 at one or both ends of the container 104. The access doors 116 allow operators to add or remove servers and other equipment to racks within the container 104 and service the racks/equipment. Each rack may provide space, electrical connections, and cooling connections for a number of identical or dissimilar servers. In one embodiment, the access doors 116 may be locked from the outside. The arrangement of the racks, servers, and cooling distribution assemblies is shown and described herein.

External to the container 104, a number of single-phase pumps 108 and dry coolers 112 are affixed to external surfaces of the container104. Single-phase pumps 108 refer to a secondary coolant transferred by the pumps 108 as having only a single phase (i.e. liquid). The pumps 108 are affixed to side surfaces of the container 104 and circulate a liquid coolant of a secondary cooling loop throughout the racks and servers. A number of dry coolers 112 are attached to a top surface of the container 104. In the illustrated embodiment, three single-phase pumps 108 and 16 dry coolers 112 are affixed to the container 104. Appropriate perforations in side and/or top surfaces of the container 104 provide access for coolant pipes and power/control cables.

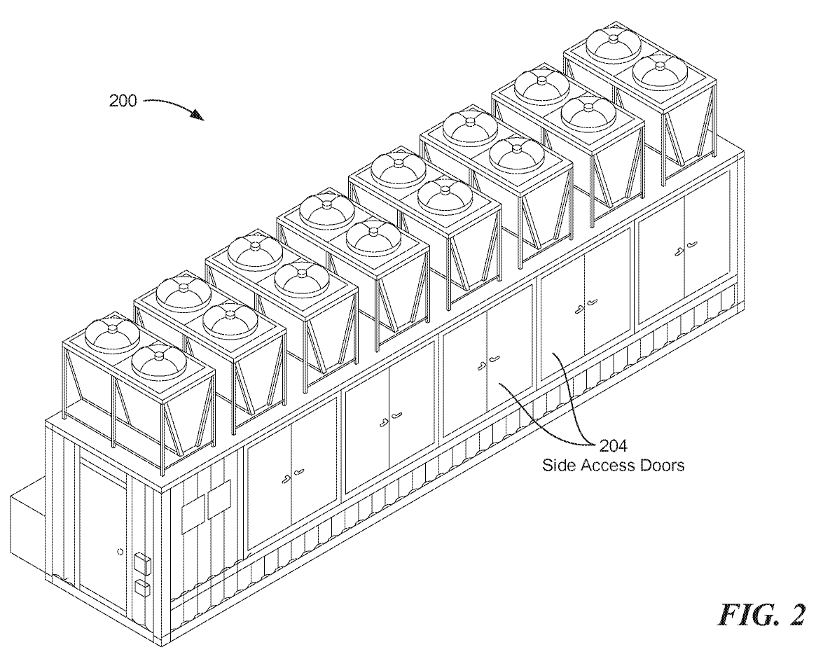

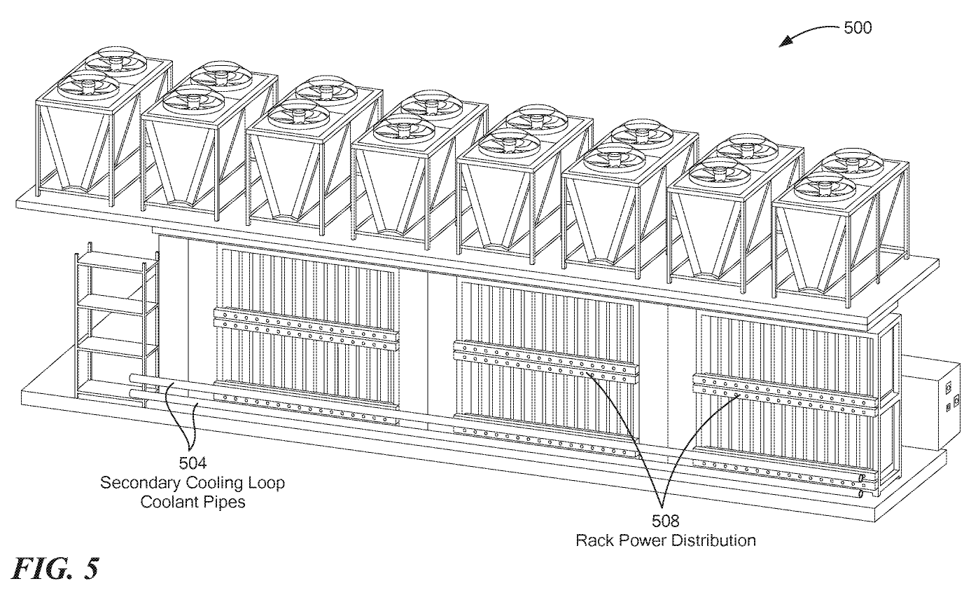

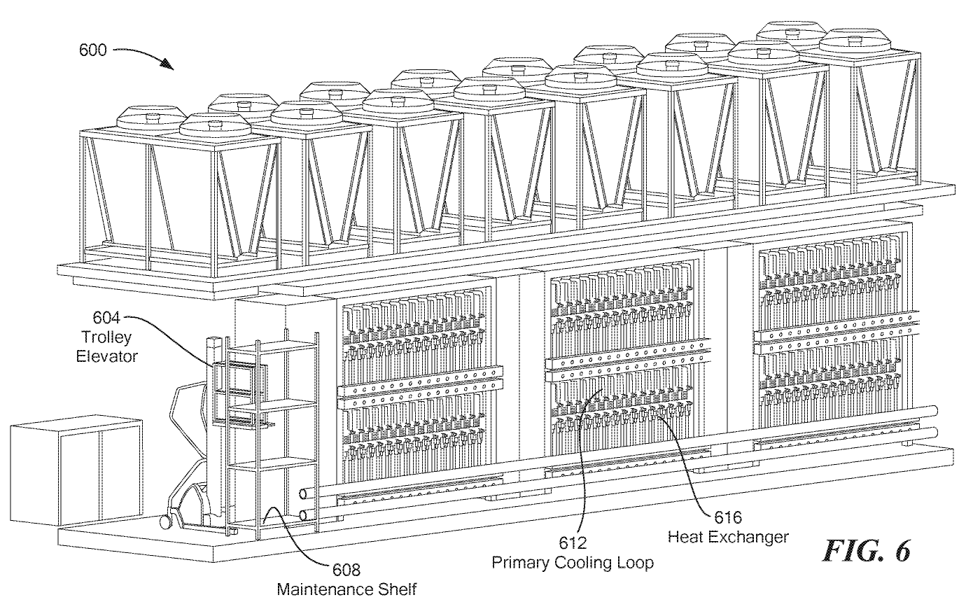

Referring to FIG. 2, a second front external isometric view of a shipping container based data center cooling system 200 in accordance with illustrative embodiments of the invention is shown. The second isometric view is from a right perspective. In addition to the single-phase pumps 108 and the dry coolers 112, the right side may have a number of side access doors 204. The side access doors 204 allow rear access to the racks, server cassettes, cabling, and coolant pipes for servicing. In the illustrated embodiment, the racks are generally positioned with the rear of the racks and server cassettes facing and proximate with the right side of the container 104 (see FIGS. 5 and 6). The side access doors 204 allow service personnel to add, remove, or adjust cabling or pipes related to data transfers, power distribution, and cooling.

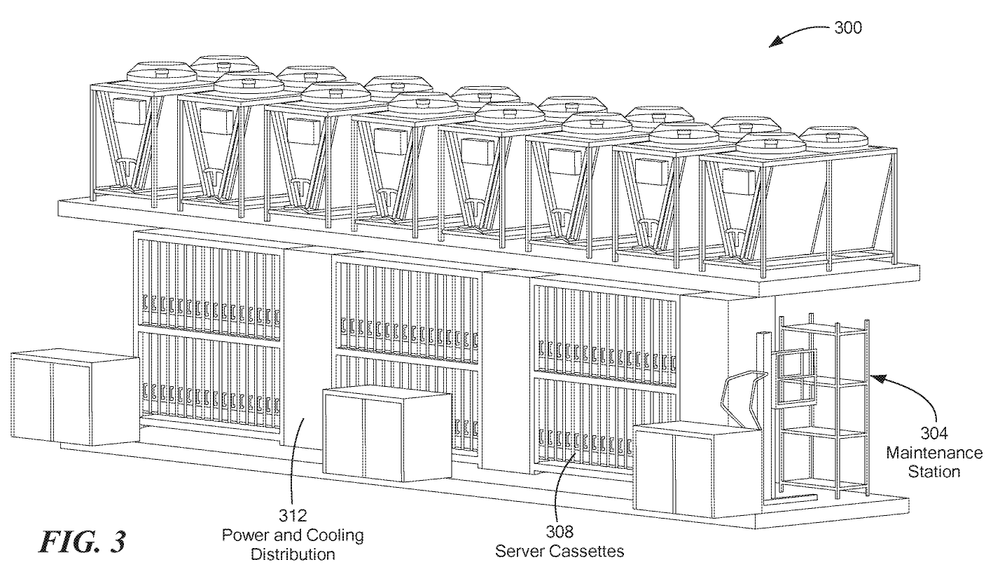

Referring to FIG. 3, a first front internal isometric view of a data center cooling system with side container surfaces removed 300 in accordance with illustrative embodiments of the invention is shown. The second isometric view is from a left perspective and illustrates the internal equipment configuration of the container data center cooling system 100.

In various embodiments, the container 104 may include a number of server cassettes 308. Typically, each server cassette 308 contains a single server motherboard. Space may be provided between the server cassettes 308 for power and cooling distribution 312. The power and cooling distribution 312 may include coolant pipes and manifolds and various forms of electrical and control cabling or buss bars.

FIG. 3 also shows a maintenance station 304 for servicing the server cassettes 308. Space may be provided for server cassette 308 installation and removal equipment, server cassette 308 offline storage, and server cassette 308/server assembly/disassembly and repair.

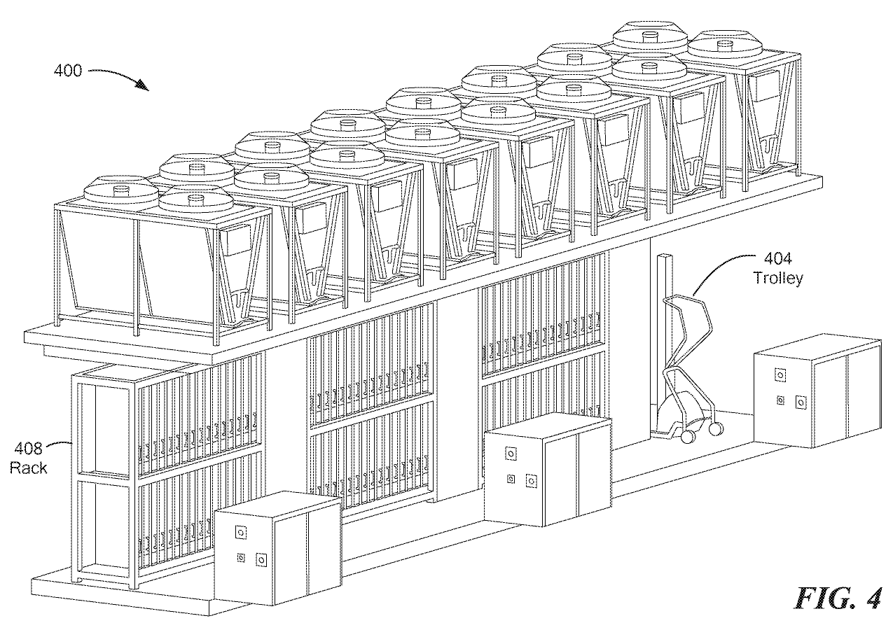

Referring to FIG. 4, a first rear internal isometric view of a data center cooling system with side container surfaces removed 400 in accordance with illustrative embodiments of the invention is shown. The first isometric view is from a left perspective and illustrates the internal equipment configuration of the container data center cooling system 100.

FIG. 4 shows a rack 408 containing operating locations the server cassettes 308 are installed to. In the illustrated embodiment, there are three racks 408 and each rack 408 stores 16 server cassettes 308. In other embodiments, the size of server cassettes 308, the number of shelves of server cassettes 308, server cassettes 308 per shelf, and number of racks 408 may vary from what is shown in FIG. 4. The number of racks 408 in a container 104 may be limited by the length of the container 104.

In one embodiment, the rack 408 may have a 33.5” wide form factor common with other rack equipment or may have a custom form factor. In one embodiment, the rack 408 may be moved via casters to other locations within the container 104, although once in place and fully installed tends to stay in the same location. The rack 408 may include a control panel (not shown) to provide local management resources to the server cassettes 308, power supplies in the container 104, or other rack 408 resources. In one embodiment, the control panel may have one or more wired or wireless interfaces to allow management by external management computers and operators.

FIG. 4 also shows a trolley 404, which is used to install or remove server cassettes 308 from racks 408 and transport server cassettes 308 to/from the maintenance station 304. Server cassettes 308 may weigh in excess of 100 lbs. and require the trolley 404 to safely move the server cassettes 308. The trolley 404 may have wheels to move along the floor of the container 104. In one embodiment, the wheels may be motorized.

Referring to FIG. 5, a second front internal isometric view of a data center cooling system with side container surfaces removed 500 in accordance with illustrative embodiments of the invention is shown. The second isometric view is from a right perspective and illustrates the internal equipment configuration of the container data center cooling system 100.

FIG. 5 illustrates some of the components between the rack 408 and server cassettes 308 and the right wall of the container 104. All cabling has been omitted for clearer presentation.

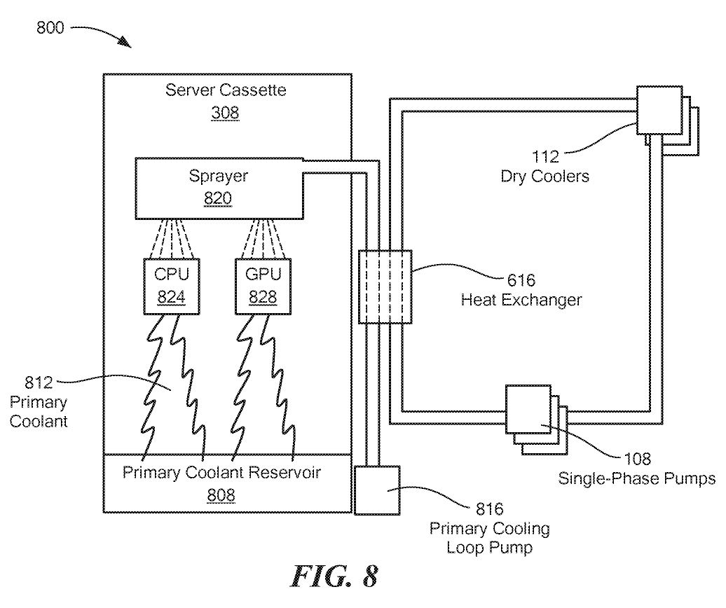

Illustrated are secondary cooling loop coolant pipes 504, as shown in FIG. 8. The secondary coolant pipes 504 carry a secondary coolant, such as water, between the single-phase pumps 108, the dry coolers 112, and the heat exchangers 616 attached to the rear of each server cassette 308. One of the two illustrated pipes may supply cooled secondary coolant to each of the server cassettes 308 and the other illustrated coolant pipe may return heated secondary coolant from the server cassettes 308 to the single phase pumps 108.

Also shown in FIG. 5 are rack power distribution strips 508. The rack power distribution strips 508 distribute power from one or more power source inputs on the container 104 (not shown) to each server cassette 308. In one embodiment, short power cables distribute power from a rack power distribution strip 508 to each of the server cassettes 308.

Referring to FIG. 6, a second front internal isometric view of a data center cooling system with side container surfaces removed 600 in accordance with illustrative embodiments of the invention is shown. The second isometric view is from a right perspective and illustrates the internal equipment configuration of the container data center cooling system 100.

FIG. 6 illustrates additional features of the container data center cooling system 100. Each server cassette 308 includes a primary cooling loop 612 that circulates a primary liquid coolant (e.g., dielectric oil or water/glycol combination) through the server cassette 308 and a heat exchanger 616 affixed to the server cassette 308. In the illustrated embodiment, the heat exchanger 616 is affixed to a rear surface of each server cassette 308. However, in other embodiments the heat exchanger 616 may be affixed to other surfaces of the server cassette 308 or be disposed within the server cassette 308 itself. The heat exchanger 616 provides the interface between the primary cooling loop 612 of each server cassette 308 and the secondary cooling loop for the container data center cooling system 100. The components of the primary 612 and secondary cooling loops are shown and described in FIG. 8. The primary cooling loop 612 of each server cassette 308 is fluidly isolated from the other primary cooling loops 612. Fluid isolation refers to the absence of shared liquid flow paths between primary cooling loops 612 of different server cassettes 308 and between the primary 612 and secondary cooling loops.

In one embodiment, valves may be provided between the secondary cooling loop and each heat exchanger 616. The valves may prevent secondary coolant leakage when a server cassette 308 is removed from a rack 408. Hence, when valves for a server cassette 308 are closed, removal of a server cassette 308 from the rack 408 or the sipping container 104 does not interrupt circulation of the secondary liquid cooling loop to remaining server cassettes 308. By fluidly isolating the primary cooling loop within each server cassette 308, servicing of a single cassette may be performed without exposing the secondary cooling loop to leakage or requiring shutdown of adjacent server cassettes. In one embodiment, the valves may be manually controlled as part of a server cassette 308 removal or installation process. In another embodiment, the valves may be remotely controlled (e.g., by a maintenance computer at the maintenance station 304) as part of the server cassette 308 removal or installation process.

FIG. 6 also illustrates additional features of the maintenance station 304. The trolley 404 includes a trolley elevator 604 that raises and lowers a platform that holds server cassettes 308. In a preferred embodiment, the trolley elevator 604 is coupled to an actuator (e.g., electric motor) controlled by an operator that raises and lowers the platform. In the raised position, the elevator 604 accesses the upper shelf of the rack 408 to install or remove a server cassette 308. In the lowered position, the elevator 604 accesses the lower shelf of the rack 408 to install or remove a server cassette 308. The trolley 404 may typically transport server cassettes 308 between the rack 408 and the maintenance station 304 in the lowered position, or a similar lowered position. The maintenance station 304 may also include a maintenance table 704 to service server cassettes 308 and one or more maintenance shelves 608 to store server cassettes 308 either awaiting maintenance or after maintenance.

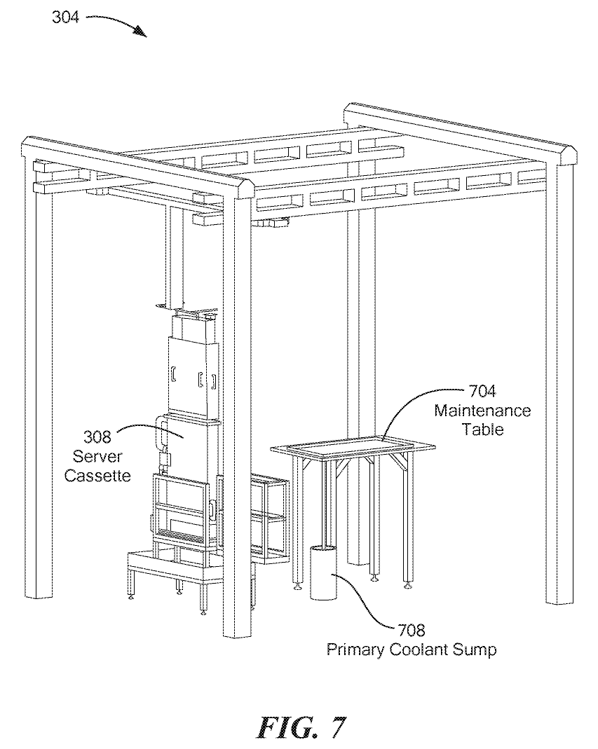

Referring to FIG. 7, a maintenance station 304 of a container-based data center cooling system in accordance with illustrative embodiments of the invention is shown. The maintenance station 304 may include various features to assist in installing, replacing, and maintaining server cassettes 308. The maintenance station 304 may be required for the container data center cooling system 100 for remote installations outside a building or where no suitable maintenance facility already exists.

FIG. 7 illustrates a shelf holding a server cassette 308 and a maintenance table 704. An operator may move the server cassette 308 from the shelf to the maintenance table 704 for disassembly and from the maintenance table 704 to the shelf. Once on the maintenance table 704, the server cassette 308 may be disassembled and the primary coolant drained to a primary coolant sump 708. The operator may remove or replace the server motherboard or other components of the server cassette 308, including a primary coolant pump (not shown) or the heat exchanger 616. The trolley 404 and trolley elevator 604 transfer server cassettes 308 between the rack 408 and the shelf of the maintenance station 304.

In addition to the various components illustrated and described herein, the container data center cooling system 100 may include interior lighting and climate control (e.g., HVAC) for the areas in front of and behind the racks 408 and the maintenance station 304. Preferably, the climate control system is able to maintain an ideal operating temperature, airflow, and humidity control reflecting a data center environment for the racks 408 and server cassettes 308. This should also be maintained for some time period reflecting operator access to the container 104 through the access door 116 and/or side access doors 204.

In one embodiment, the maintenance station 304 may include one or more computing devices to provide configuration and management services for servers within the server cassettes 308, the single-phase pumps 108, and the dry coolers 112. The one or more computing devices may be networked to each of the server cassettes 308 in the racks 408 and to one or more computing devices external to the container 104. In one embodiment, network cabling may interconnect networked devices within the container 104. In another embodiment, wireless networking may be partially or totally used.

Referring to FIG. 8, a block diagram of primary and secondary cooling loops of a container-based data center cooling system 800 in accordance with illustrative embodiments of the invention is shown. The container-based data center cooling system 100 includes a number of primary cooling loops 612 associated with the server cassettes 308. The primary cooling loops 612 interface with a secondary cooling system of the container-based data center cooling system 100 through heat exchangers 616 of the server cassettes 308. Heat from each primary cooling loop 612 is transferred to the secondary cooling loop and cooled secondary coolant of the secondary cooling loop is transferred to each primary cooling loop 612.

Heated primary coolant 812 of each server cassette 308 is temporarily stored in a primary coolant reservoir 808 at the bottom of each server cassette 308. A primary cooling loop pump 816 affixed to the rear of the server cassettes 308 suctions the primary coolant 812 from the primary coolant reservoir 808 and pressurizes the heated primary coolant 812 through the heat exchanger 616. The primary coolant 812 is cooled in the heat exchanger 616 and is returned to one or more sprayers 820 or coolant delivery element in the server cassette 308. Each sprayer 820 sprays cooled primary coolant 812 onto central processing unit (CPU) heat sinks 824, graphics processing unit (GPU) heat sinks 828, and any other hot electrical components requiring liquid cooling. The hot electrical components heat the primary coolant 812, which drips by gravity through openings at the top of the primary coolant reservoir 808 and the process repeats.

The secondary cooling loop includes the secondary cooling loop coolant pipes 504, the single phase pumps 108, and the dry coolers 112. The single-phase pumps suction the secondary coolant through the heat exchanger 616 and the secondary cooling loop coolant pipes 504 and pressurize the secondary coolant to the dry coolers 112. The dry coolers 112 cool the heated secondary coolant and return cooled secondary coolant to the heat exchanger 616 to repeat the process.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A containerized data center cooling system, comprising:
a shipping container defining an interior volume;
a plurality of server cassettes removably supported within the interior volume, each server cassette comprising:
one or more heat-generating electronic components;
a self-contained primary liquid cooling loop disposed entirely within each server cassette, the primary liquid cooling loop including:
a primary coolant reservoir;
a pump configured to circulate a primary liquid coolant; and
at least one coolant delivery element configured to deliver the primary liquid coolant directly onto the one or more heat-generating electronic components; and
a heat exchanger affixed to the server cassette and thermally coupled to the primary liquid cooling loop.

2. The system of claim 1, further comprising:
a secondary liquid cooling loop fixed relative to the shipping container and thermally coupled to the heat exchanger of each server cassette, the secondary liquid cooling loop comprising:
coolant piping;
one or more single-phase pumps, configured to circulate a secondary liquid coolant through the coolant piping; and
one or more heat rejection devices, coupled through the coolant piping to the one or more single-phase pumps, configured to remove heat from the secondary liquid coolant.

3. The system of claim 2, wherein the one or more heat rejection devices include dry coolers mounted on one or more exterior surfaces of the shipping container.

4. The system of claim 2, wherein the primary liquid cooling loop of each server cassette is fluidly isolated from the primary liquid cooling loops of other server cassettes and from the secondary liquid cooling loop.

5. The system of claim 4, wherein the primary liquid cooling loop of each server cassette is thermally coupled to the secondary liquid cooling loop through the heat exchanger.

6. The system of claim 2, wherein removal of a server cassette from the shipping container does not interrupt circulation of the secondary liquid cooling loop to remaining server cassettes.

7. The system of claim 1, further comprising an internal maintenance station positioned within the shipping container and configured to permit removal, servicing, and reinstallation of individual server cassettes entirely within the container.

8. The system of claim 7, further comprising an internal trolley movable within the shipping container and configured to transport server cassettes between racks removably supporting the plurality of server cassettes and the maintenance station.

9. The system of claim 8, wherein the trolley includes a vertically adjustable elevator configured to align a server cassette with different shelf heights.

10. A transportable data center cooling apparatus, comprising:
a shipping container;
a plurality of removable server cassettes disposed within the shipping container, each server cassette comprising an internal, closed primary liquid cooling loop configured to cool one or more electronic components within the server cassette; and
a secondary liquid cooling loop thermally coupled to each server cassette by a respective cassette-mounted heat exchanger.

11. The apparatus of claim 10, wherein the primary liquid cooling loop of each server cassette is operable independently of the primary liquid cooling loops of other server cassettes.

12. The apparatus of claim 10, wherein the secondary liquid cooling loop is configured to continue cooling remaining server cassettes while one server cassette is decoupled from the secondary liquid cooling loop.

13. The apparatus of claim 10, further comprising an internal maintenance station positioned within the shipping container and configured to permit removal, servicing, and reinstallation of individual server cassettes entirely within the container.

14. The apparatus of claim 13, further comprising an internal trolley movable within the shipping container and configured to transport server cassettes between the maintenance station and racks within the container removably supporting the plurality of server cassettes.

15. The apparatus of claim 14, wherein the trolley includes a vertically adjustable elevator configured to align a server cassette with different shelf heights.

16. A method of cooling and servicing a containerized data center, comprising:
circulating a secondary liquid coolant through a secondary cooling loop fixed relative to a shipping container;
circulating a primary liquid coolant within a first server cassette using a primary cooling loop disposed entirely within the first server cassette;
thermally coupling the primary cooling loop to the secondary cooling loop through a heat exchanger mounted to the first server cassette;
removing the first server cassette from a rack location within the shipping container; and
servicing the first server cassette at a maintenance station within the shipping container.

17. The method of claim 16, wherein removing the server cassette includes moving the server cassette using a wheeled trolley within the container to the maintenance station.

18. The method of claim 16, wherein servicing the first server cassette includes draining and refilling a primary liquid coolant associated with the server cassette.

19. The method of claim 16, wherein circulating the primary liquid coolant within the first server cassette comprises spraying the primary liquid coolant onto one or more heat sinks within the first server cassette.

20. The method of claim 16, wherein the primary liquid cooling loop of the first server cassette is operable independently of the primary liquid cooling loops of other server cassettes.
